(19) United States
(12) Patent Application Publication
(10) Pub. No.: US 2024/0282651 A1
(43) Pub. Date: Aug. 22, 2024

(54) ELECTRONIC ELEMENT MOUNTING SUBSTRATE

(71) Applicant: KYOCERA Corporation, Kyoto-shi, Kyoto (JP)

(72) Inventors: Futoshi ONIMARU, Kyoto-shi (JP); Jyoji KAWASAKI, Kyoto-shi (JP); Arata INOMOTO, Kyoto-shi (JP); Atsuo YAMAMOTO, Kyoto-shi (JP)

(73) Assignee: KYOCERA Corporation, Kyoto-shi, Kyoto (JP)

(21) Appl. No.: 18/274,056

(22) PCT Filed: Jan. 25, 2022
(86) PCT No.: PCT/JP2022/002491

§ 371 Date: Jul. 25, 2023

(30) Foreign Application Priority Data
Jan. 29, 2021 (JP) 2021-013864

(51) Int. Cl. H01L 23/14

(52) U.S. Cl. CPC H01L 23/14

(57) ABSTRACT

An electronic element mounting substrate including: a substrate having, on an upper surface thereof, a mounting region on which an electronic element is to be mounted; and a first metal film located in the mounting region, in which the first metal film has a first region including a center portion of the first metal film and a second region located in at least a part of a periphery of the first region, and the second region has a thick film portion in which a film thickness of the second region is greater than a film thickness of the first region. Thus, a connection material connecting the mounting region and the electronic element is suppressed from unintentionally flowing to the outside. In addition, spreading of the connection material is promoted.

### TECHNICAL FIELD

The present disclosure relates to an electronic element mounting substrate.

### BACKGROUND OF INVENTION

Recently, an electronic element mounting substrate is known. The electronic element mounting substrate includes a substrate having, on an upper surface thereof, a mounting region on which an electronic element is to be mounted. One example of such an electronic element mounting substrate is disclosed in Patent Document 1.

### CITATION LIST

### Patent Literature

Patent Document 1: JP 2006-208129 A

### SUMMARY

An electronic element mounting substrate according to an aspect of the present disclosure includes a substrate having, on an upper surface thereof, a mounting region on which an electronic element is to be mounted; and a first metal film located in the mounting region, in which the first metal film has a first region including a center portion of the first metal film and a second region located in at least a part of a periphery of the first region, and the second region has a thick film portion in which a film thickness of the second region is greater than a film thickness of the first region.

### BRIEF DESCRIPTION OF THE DRAWINGS

FIG. 1A is a top view illustrating an appearance of an electronic device according to a first embodiment of the present disclosure, and FIG. 1B is a vertical cross-sectional view corresponding to a line X1-X1 in FIG. 1A.

FIG. 2A is a cross-sectional view illustrating a layered structure in a first metal film, and FIG. 2B is a cross-sectional view illustrating a layered structure in a second metal film.

FIG. 3 is a view illustrating an example of a method of providing a gold coating on a surface of a nickel coating, and is a perspective view illustrating a step of packing an intermediate body of an electronic element mounting substrate in a jig.

FIG. 4 is a view illustrating an example of a method of providing the gold coating on the surface of the nickel coating, and is a front view illustrating a step of plating the intermediate body packed in the jig.

FIG. 5 is a top view illustrating a rough trend of a distribution of a film thickness of the gold coating provided on the intermediate body in the step illustrated in FIG. 4.

FIG. 6A is a top view illustrating an appearance of an electronic device according to a second embodiment of the present disclosure, FIG. 6B is a vertical cross-sectional view corresponding to a line X1-X1 in FIG. 6A, and FIG. 6C is a variation of FIG. 6B.

FIG. 7A is a top view illustrating an appearance of an electronic device according to a third embodiment of the present disclosure, FIG. 7B is a vertical cross-sectional view corresponding to a line X1-X1 in FIG. 7A, and FIG. 7C is a variation of FIG. 7B.

FIG. 8A is a top view illustrating an appearance of an electronic device according to a fourth embodiment of the present disclosure, and FIG. 8B is a vertical cross-sectional view corresponding to a line X1-X1 in FIG. 8A.

### DESCRIPTION OF EMBODIMENTS

Hereinafter, embodiments for implementing the present disclosure will be described. For convenience of description, members having the same functions as those described above are denoted by the same reference signs, and the description thereof is not repeated in some cases.

### Configuration of Electronic Device

Hereinafter, some exemplary embodiments of the present disclosure will be described with reference to the drawings. In the following description, an electronic device is formed by mounting an electronic element on an electronic element mounting substrate. In the electronic device, any direction may be vertically upward or vertically downward, but for convenience, an orthogonal coordinate system XYZ is defined, and the positive side in the Z direction is defined as upward.

In the present disclosure, a “surface” refers not only to a surface on the front side but also a side surface and a surface on the back side. When only the surface on the front side is referred to, the term “upper surface” is used. When only the surface on the back side is referred to, the term “lower surface” is used.

### First Embodiment

Hereinafter, an electronic device 201 according to a first embodiment of the present disclosure will be described.

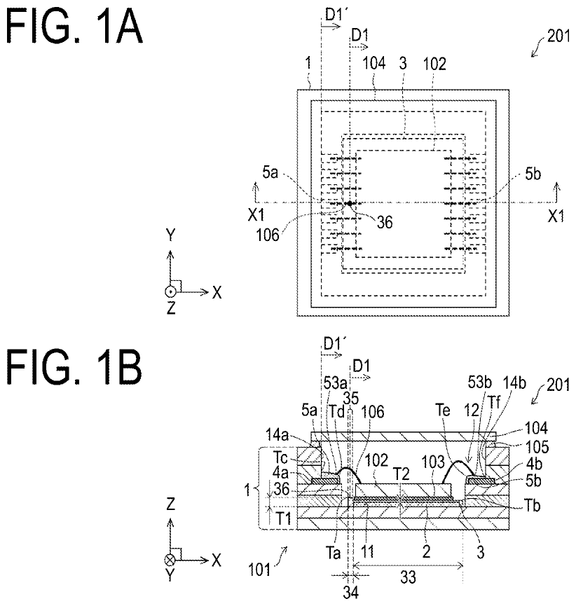

FIG. 1A is a top view illustrating the appearance of the electronic device 201 according to the first embodiment of the present disclosure, and FIG. 1B is a vertical cross-sectional view corresponding to the line X1-X1 in FIG. 1A.

The electronic device 201 includes an electronic element mounting substrate 101, an electronic element 102, a connection material 103, a lid body 104, a lid bonding material 105, and a bonding wire 106. The electronic element mounting substrate 101 includes a substrate 1, a metallized layer 2, a first metal film 3, electrode pads 4a and 4b, and second metal films 5a and 5b.

For the purpose of simplifying the description, the electrode pads 4a and 4b, the second metal films 5a and 5b, and the bonding wire 106 will be collectively described in the latter half section (second metal film) of the embodiment of the present disclosure. Therefore, in the description of each embodiment before this section, the description of the electrode pads 4a and 4b, the second metal films 5a and 5b, and the bonding wire 106 will be omitted.

The substrate 1 is a base for mounting the electronic element 102, and has a mounting region 11 on which the electronic element 102 is to be mounted. The mounting region 11 is located on the upper surface of the substrate 1. Examples of the material of the substrate 1 include an electrically insulating ceramic and a resin (e.g., a plastic). Examples of the electrically insulating ceramic include an aluminum oxide sintered body, a mullite sintered body, a silicon carbide sintered body, an aluminum nitride sintered body, a silicon nitride sintered body, and a glass ceramic sintered body. Examples of the resin include an epoxy resin, a polyimide resin, an acrylic resin, a phenol resin, and a fluorine-based resin. Examples of the fluorine-based resin include a polyester resin and a tetrafluoroethylene resin.

The substrate 1 is not limited to a single layer, but can be a layered structure with a plurality of layers. When the substrate 1 has a layered structure with a plurality of layers, each of the plurality of layers may be made of the above-described material. In FIG. 1B, the substrate 1 has a layered structure having six layers. However, the number of layers of the substrate 1 is not limited to six, and may be one or more and five or less, or may be seven or more. In FIG. 1B, an opening 12 in which the electronic element 102 and the like are accommodated is formed in the substrate 1. However, the substrate 1 may have a shape (for example, a flat plate) such that the opening 12 is not formed.

The size of the substrate 1 in a plan view is, for example, from 0.3 mm to 10 cm. Examples of the shape of the substrate 1 in a plan view include a square and a rectangle. The thickness of the substrate 1 is, for example, 0.2 mm or more.

An electrode may be provided on the surface of the substrate 1. The electrode may electrically connect the electronic element mounting substrate 101 to an external circuit board, or may electrically connect the electronic device 201 to an external circuit board.

Inside the substrate 1, internal wiring formed between a plurality of layers and a through-hole conductor vertically connecting the internal wiring may be provided. The internal wiring and the through-hole conductor may be exposed on the surface of the substrate 1. An electrical connection between the electrode and another member may be realized by the internal wiring and the through-hole conductor.

The metallized layer 2 is provided on the surface of the substrate 1, and more specifically, provided in the mounting region 11 of the substrate 1. The metallized layer 2 can be electrically connected to the electronic element 102.

When the substrate 1 is made of an electrically insulating ceramic, the metallized layer 2 is made of, for example, any one of tungsten (W), molybdenum (Mo), manganese (Mn), silver (Ag), and copper (Cu), or an alloy containing at least one of the aforementioned. When the substrate 1 is made of a resin, the metallized layer 2 is made of, for example, any one of copper, gold (Au), aluminum (Al), nickel (Ni), molybdenum, and titanium (Ti), or an alloy containing at least one of these metals. The same applies to each of the electrode, the internal wiring, and the through-hole conductor.

The first metal film 3 is located in the mounting region 11, and more specifically, is provided on the surface of the metallized layer 2.

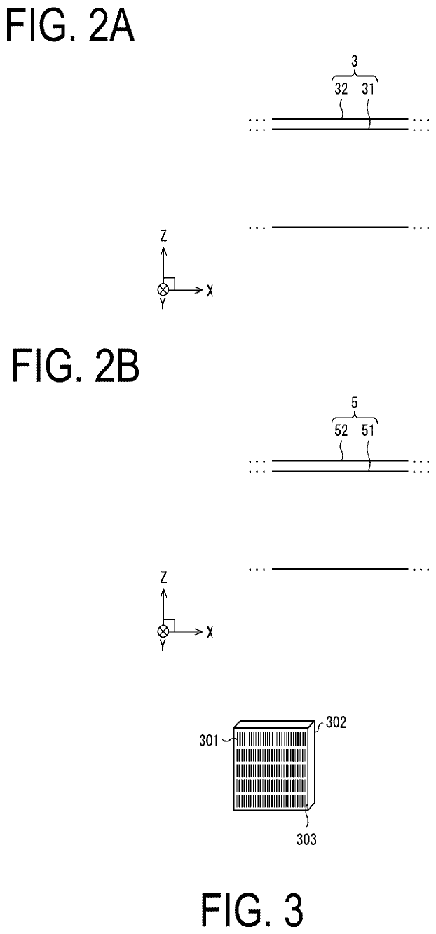

FIG. 2A is a cross-sectional view illustrating the layered structure in the first metal film 3, and FIG. 2B is a cross-sectional view illustrating the layered structure in a second metal film 5. The second metal film 5 is any one of the second metal films 5a and 5b.

As illustrated in FIG. 2A, the first metal film 3 includes a nickel coating 31 and a gold coating 32. The nickel coating 31 contains nickel as a main component, and is provided on the substrate 1 side with respect to the gold coating 32. The film thickness of the nickel coating 31 is, for example, from 0.03 μm to 3.0 μm. The gold coating 32 contains gold as a main component, and is provided on the opposite side to the substrate 1 with respect to the nickel coating 31 and covers at least a part of the nickel coating 31. That is, the gold coating 32 may cover the entirety of the nickel coating 31, or may cover a part of the nickel coating 31. The film thickness of the gold coating 32 is, for example, from 0.03 μm to 0.30 μm. The first metal film 3 preferably has a layered structure, but may have a single-layer structure. The same applies to the second metal film 5 described below.

The electronic element 102 is fixed on the mounting region 11. Examples of the electronic element 102 include a CCD-type imaging element, a CMOS-type imaging element, a light emitting element such as an LED or an LD, and an integrated circuit. CCD is an abbreviation of “Charge Coupled Device”. CMOS is an abbreviation of “Complementary Metal Oxide Semiconductor”. LED is an abbreviation of “Light Emitting Diode”. LD is an abbreviation of “Laser Diode”. The electronic element 102 is connected to the first metal film 3 via the connection material 103. Examples of the material of the connection material 103 include silver epoxy and thermosetting resin.

The lid body 104 is fixed to the upper surface of the substrate 1 and covers the electronic element 102. In a case where the electronic element 102 is any one of the imaging element and the light emitting element exemplified above, as an example of a material of the lid body 104, a material having high transparency such as a glass material is exemplified. In the case where the electronic element 102 is the integrated circuit exemplified above, examples of the material of the lid body 104 include a metal material and an organic material.

A frame-shaped body surrounding the electronic element 102 and supporting the lid body 104 may be provided on the upper surface of the electronic element mounting substrate 101. The frame-shaped body need not be provided in the electronic element mounting substrate 101. The material of the frame-shaped body and the material of the substrate 1 may be the same or different.

The lid bonding material 105 bonds the substrate 1 and the lid body 104. Examples of the material of the lid bonding material 105 include a thermosetting resin, low-melting-point glass, and a brazing material made of a metal component. When a frame-shaped body made of a material different from that of the substrate 1 is provided on the electronic element mounting substrate 101, the lid bonding material 105 may be made of the same material as that of the frame-shaped body. At this time, by providing the lid bonding material 105 to be thick, the lid bonding material 105 can have a function of bonding the substrate 1 and the lid body 104 and can function as a frame-shaped body that supports the lid body 104. In a case where a frame-shaped body made of the same material as the substrate 1 is provided in the electronic element mounting substrate 101, the frame-shaped body and the lid body 104 may be configured as the same member.

### Production Method

An example of a method for manufacturing the electronic element mounting substrate 101 and the electronic device 201 of the present embodiment will be described. An example of the manufacturing method described below is a method of manufacturing the substrate 1 using a multi-piece wiring substrate.

(a) First, a ceramic green sheet constituting the substrate 1 is formed. For example, in order to obtain the substrate 1 made of an aluminum oxide (Al₂O₃)-based sintered body, a powder of, for example, silica (SiO₂), magnesia (MgO), or calcia (CaO) is added as a sintering aid to Al₂O₃ powder. Further, a suitable binder, a solvent, and a plasticizer are added, and then a mixture thereof is kneaded to form a slurry. Then, multi-piece ceramic green sheets are obtained by a formation method, such as a doctor blade method or a calendar roll method.

When the substrate 1 is made of, for example, a resin, the substrate 1 can be formed by a transfer molding method, an injection molding method, pressing with a mold, or the like, using a mold that can be molded into a predetermined shape. The substrate 1 may be made of a base material made of glass fibers impregnated with a resin, such as a glass epoxy resin. In this case, the substrate 1 can be formed by impregnating a base material made of glass fibers with a precursor of an epoxy resin and thermally curing the epoxy resin precursor at a predetermined temperature.

(b) Next, by using a screen printing method or the like, a metal paste is applied to or filled in portions of the ceramic green sheet obtained in the step (a) where the electrode pads, the metallized layer 2, the internal wiring electrical conductor and/or the internal through-hole conductor are to be formed. This metal paste is created so as to have appropriate viscosity by adding a suitable solvent and binder to a metal powder formed of the above-described metal materials, and kneading the mixture. The metal paste may contain glass or ceramic in order to increase the bonding strength with the substrate 1.

When the substrate 1 is made of a resin, the electrode pads, the metallized layer 2, the internal wiring electrical conductor and/or the internal through-hole conductor can be formed by a sputtering method, a vapor deposition method or the like. The above may be manufactured by using a plating method after providing a metal film on the surface.

(c) Next, the above-described green sheet is processed by using a die or the like. Here, in the case where the substrate 1 has an opening portion, a notch, or the like, the opening portion, the notch, or the like may be formed at a predetermined position on the green sheet to be the substrate 1.

(d) Next, the ceramic green sheets to be the respective insulating layers of the substrate 1 are layered and pressed. In this manner, green sheets to be the insulating layers may be layered to fabricate a ceramic green sheet layered body to be the substrate 1. At this time, by using a die, punching, a laser, or the like, an opening portion may be provided at a predetermined position on the ceramic green sheets of a plurality of layers that have been layered.

(e) Next, the ceramic green sheet layered body is fired at a temperature of about 1500° C. to 1800° C. to obtain a multi-piece wiring substrate in which a plurality of substrates 1 are arrayed. In this step, the above-described metal paste is fired simultaneously with the ceramic green sheet to be the substrate 1 to form the electrode pads, the internal wiring electrical conductor, and/or the internal through-hole conductor.

(f) Next, the multi-piece wiring substrate obtained by firing is divided into a plurality of substrates 1. For this division, a method in which a dividing groove is formed in the multi-piece wiring substrate along a portion to be the outer edge of the substrate 1, and the multi-piece wiring substrate is broken and divided along the dividing groove can be used, or a method in which the multi-piece wiring substrate is cut along a portion to be the outer edge of the substrate 1 by a slicing method or the like can be used. The dividing grooves can be formed by cutting into the multi-piece wiring substrate to a depth smaller than the thickness of the multi-piece wiring substrate by using a slicing device after firing. The dividing grooves may be formed by pressing a cutter blade against the ceramic green sheet layered body for the multi-piece wiring substrate or by cutting the ceramic green sheet layered body with a slicing device to a depth smaller than the thickness of the ceramic green sheet layered body. Before or after the multi-piece wiring substrate is divided into the plurality of substrates 1, the electrode pads, the metallized layer 2, the internal wiring electrical conductor, and the internal through-hole conductor may be plated thereon.

(g) Next, the electronic element 102 is mounted on the mounting region 11 of the substrate 1. The electronic element 102 is electrically bonded to the substrate 1 by a connection member such as wire bonding. At this time, the electronic element 102 or the substrate 1 is provided with the connection material 103 or the like and fixed to the substrate 1. Alternatively, the lid body 104 may be bonded after the electronic element 102 is mounted on the substrate 1.

the electronic device 201 can be fabricated by fabricating the substrate 1 and mounting the electronic element 102 as in the steps (a) to (g) described above. The order of the steps (a) to (g) is not specified as long as it is a workable order.

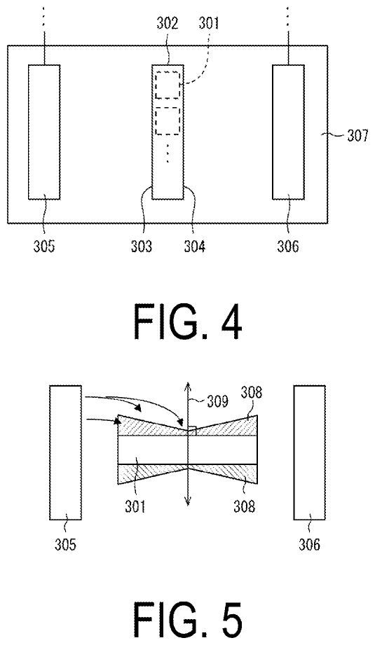

All the steps for obtaining the electronic element mounting substrate 101 from the multi-piece wiring substrate have been described above, and the plating method will be described in detail below. FIG. 3 is a view illustrating an example of a method of providing the gold coating 32 on the surface of the nickel coating 31, and is a perspective view illustrating a step of packing an intermediate body 301 of the electronic element mounting substrate 101 in a jig 302. FIG. 4 is a view illustrating an example of a method of providing the gold coating 32 on the surface of the nickel coating 31, and is a front view illustrating a step of plating the intermediate body 301 packed in the jig 302. The intermediate body 301 includes the nickel coating 31 similarly to the electronic element mounting substrate 101, and, unlike the electronic element mounting substrate 101, does not include the gold coating 32.

As an example of a method of providing the gold coating 32 on the surface of the nickel coating 31 (covering at least a part of the nickel coating 31), a method including the steps illustrated in FIGS. 3 and 4 is considered.

In the step illustrated in FIG. 3, the intermediate body 301 is packed in a jig 302. The outline of the jig 302 may be a rectangular parallelepiped as illustrated in FIG. 3. At this time, in the jig 302, a large number of spaces are formed along the normal direction of a pair of surfaces 303 and 304 (see FIG. 4) having the largest area among the surfaces constituting the rectangular parallelepiped. Each of the plurality of spaces is filled with the intermediate body 301. The number of spaces is, for example, about 250.

In the step illustrated in FIG. 4, first, the jig 302 filled with the intermediate body 301 and gold electrodes 305 and 306 are placed in a gold complex bath 307. Then, the surfaces 303 and 304 are made to oppose the gold electrodes 305 and 306, respectively, and the intermediate body 301 packed in the jig 302 is subjected to plating to provide the gold coating 32 on the intermediate body 301.

After the step illustrated in FIG. 4, the intermediate body 301 provided with the gold coating 32 is subjected to cleaning. At this time, the intermediate body 301 provided with the gold coating 32 may be removed from the jig 302 and cleaned, but the intermediate body 301 is preferably cleaned while the intermediate body 301 is packed in the jig 302. In other words, it is preferable that the intermediate body 301 provided with the gold coating 32 be cleaned together with the jig 302 (without removing the intermediate body 301 provided with the gold coating 32 from the jig 302). Thus, a step of packing the intermediate body 301 provided with the gold coating 32 in a jig different from the jig 302 can be omitted, whereby the number of manufacturing steps of the electronic element mounting substrate 101 can be reduced.

FIG. 5 is a top view illustrating a trend 308, which is rough, of the film thickness distribution of the gold coating 32 provided on the intermediate body 301 in the step illustrated in FIG. 4. The trend 308 indicates a trend that the film thickness of the gold coating 32 provided on the intermediate body 301 increases as the thickness from the intermediate body 301 increases. In the step illustrated in FIG. 4, the intermediate body 301 is disposed such that a normal direction 309 of the upper surface and the lower surface of the intermediate body 301 is substantially perpendicular to the direction in which the gold electrode 305 and the gold electrode 306 are arranged (the horizontal direction in the drawing). According to the step illustrated in FIG. 4, the trend 308 includes two components (1) and (2) to be described below.

As another method of fabricating the first metal film 3 of the electronic element mounting substrate 101 of the present embodiment, for example, a method of fabricating the first metal film 3 by plating by using an electrolytic plating method is exemplified. In the formation of the plating film by the electrolytic plating method, changing the resistance of the electrolytic plating pattern through which a current is passed can be contemplated. For example, the first metal film 3 may be fabricated by decreasing the electrical resistance of the electrolytic plating pattern on a side where the plating film is thickened and increasing the electrical resistance of the other side. For example, in the formation of the plating film by the electrolytic plating method, the first metal film may be fabricated by increasing the current on the side where the plating film is thickened.

(1) The film thickness of the gold coating 32 provided on the intermediate body 301 tends to monotonically decrease with increasing distance to the gold electrode 305.

(2) The film thickness of the gold coating 32 provided on the intermediate body 301 tends to monotonically decrease with increasing distance to the gold electrode 306.

In the electronic element mounting substrate 101, the first metal film 3 has a first region 33 and a second region 34. The first region 33 is a region including a center portion of the first metal film 3. The second region 34 is a region located in at least a part of the periphery of the first region 33. The center portion of the first metal film 3 may be a central point of the first metal film 3 in a plan view or a cross-sectional view (a cross-sectional view in the film thickness direction of the substrate) of the first metal film 3, or may be a plane or a cross section of the first metal film 3 including the central point. Typically, it can be said that the relationship between the first region 33 and the second region 34 is such that the first region 33 is located inside the first metal film 3 and the second region 34 is located outside the first metal film 3 in a plan view or a cross-sectional view of the electronic element mounting substrate 101. For example, in a cross-sectional view, more than 0 and 30% or less from the end of the first metal film 3 is defined as the second region 34, and a region including the inside of the second region 34 in the first metal film 3 is defined as the first region 33. Thus, one set of the first region 33 and the second region 34 may be realized.

The second region 34 has a thick film portion 35 in which the film thickness of the second region 34 is greater than the film thickness of the first region 33. That is, a thickness T1 of the peak thickness portion 36 having a maximum thickness in the thick film portion 35 is greater than a maximum thickness T2 of the first region 33. Although the lower end of the peak thickness portion 36 is located on the substrate 1 and the lower end of the first region 33 is located on the metallized layer 2, the actual thickness of the metallized layer 2 is negligibly small with respect to the film thicknesses T1 and T2.

When the electronic element 102 is mounted, generally, the electronic element 102 is brought close to the mounting region 11 while the mounting region 11 and the rear surface of the electronic element 102 are kept substantially parallel to each other. Accordingly, the vicinity of the thick film portion 35 comes close to and comes into contact with the rear surface of the electronic element 102 earlier than the first region 33. Accordingly, the movement of the connection material 103 substantially from the thick film portion 35 to the first region 33 can be controlled. Therefore, on the side of the thick film portion 35, the connection material 103 that connects the mounting region 11 and the electronic element 102 can be suppressed from unintentionally flowing to the outside.

Since the step and/or the inclination is formed on the upper surface of the first metal film 3, the connection material 103 flows from a high place to a low place on the upper surface of the first metal film 3, and the spread of the connection material 103 can be promoted.

In the thick film portion 35, the thickness of the thick film portion 35 monotonically decreases in a direction DI from the peak thickness portion 36 having the maximum thickness toward the inside of the first metal film 3 in a plan view of the substrate 1. A specific example of the component from which the monotonic decrease is derived is any one of the components (1) and (2). The direction D1 is merely a direction, and the start point of the monotonic decrease is the peak thickness portion 36; however, the end point thereof may be anywhere up to the end portion of the first metal film 3 on the opposite side to the peak thickness portion 36.

The peak thickness portion 36 may have not only a dotted shape but also a linear shape. When the peak thickness portion 36 has a linear shape, the direction DI may be different depending on which point of the peak thickness portion 36 is selected. When the peak thickness portion 36 has a linear shape, a plurality of the directions D1 different from each other may be defined for a plurality of points on the peak thickness portion 36, and the thickness of the thick film portion 35 may monotonically decrease in the plurality of directions D1.

As a result, the components (1) and/or (2) in the example illustrated in FIGS. 3 and 4 can be effectively utilized to realize the thick film portion 35.

In the present embodiment, the entirety of the metallized layer 2 is covered with the first metal film 3. In this case, oxidation of the metallized layer 2 can be reduced. However, as described below, a part of the metallized layer 2 may be covered with the first metal film 3.

The thickness T1, which is the maximum value of the thickness of the thick film portion 35, is from 0.06 μm to 3.30 μm. Specifically, the maximum value of the film thickness of the nickel coating 31 in the thick film portion 35 is from 0.03 μm to 3.0 μ, and the maximum value of the film thickness of the gold coating 32 in the thick film portion 35 is from 0.03 μm to 0.30 μm.

The maximum thickness T2 of the first region 33 may be, for example, from 50 to 99% of the thickness T1 that is the maximum value of the thickness of the thick film portion 35.

As illustrated in FIG. 1B, points Ta and Tb of the first metal film 3 are defined from the upstream side of the direction DI described above. At this time, the film thickness of the first metal film 3 satisfies the relation of point Tb<point Ta.

### Second Embodiment

Hereinafter, the electronic device 201 according to a second embodiment of the present disclosure will be described.

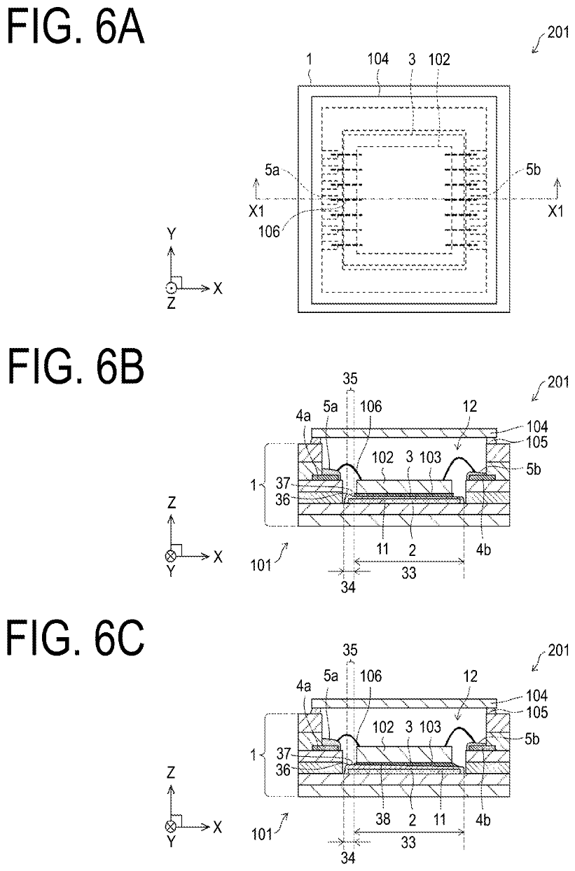

FIG. 6A is a top view illustrating the appearance of the electronic device 201 according to the second embodiment of the present disclosure, FIG. 6B is a vertical cross-sectional view corresponding to a line X1-X1 in FIG. 6A, and FIG. 6C is a variation of FIG. 6B.

In the electronic device 201 according to the second embodiment of the present disclosure, the thick film portion 35 has an inclination 37 which is a portion where the film thickness continuously increases. Here, “the film thickness continuously increases” means that, in a cross-sectional view, a portion in which the film thickness tends to increase does not consist of a step but consists of a gentle line such as an oblique line or a curved line. “The film thickness continuously increases” is a concept paired with “the film thickness discretely increases” in which a portion where the film thickness tends to increase consists of a step in a cross-sectional view. Accordingly, since the corners of the thick film portion 35 are rounded, physical damage to the electronic element 102 due to the electronic element 102 hitting the corners of the thick film portion 35 can be reduced.

The inclination 37 illustrated in FIG. 6B is rounded, but the inclination 37 may be an oblique line shape which is not rounded in a cross-sectional view.

In FIG. 6B, the thick film portion 35 clearly protrudes in the first metal film 3. On the other hand, as illustrated in FIG. 6C, the thick film portion 35 may not clearly protrude in the first metal film 3, and the upper surface of the entirety of the first metal film 3 may be smooth.

In the example illustrated in FIG. 6C, in the electronic device 201, in a cross-sectional view in the film thickness direction of the substrate 1, the first region 33 has an inclined portion 38 in which the film thickness of the first region 33 decreases with increasing distance from the thick film portion 35. Thereby, the movement of the connection material 103 from the thick film portion 35 to the first region 33 side can be controlled more suitably.

### Third Embodiment

Hereinafter, the electronic device 201 according to a third embodiment of the present disclosure will be described.

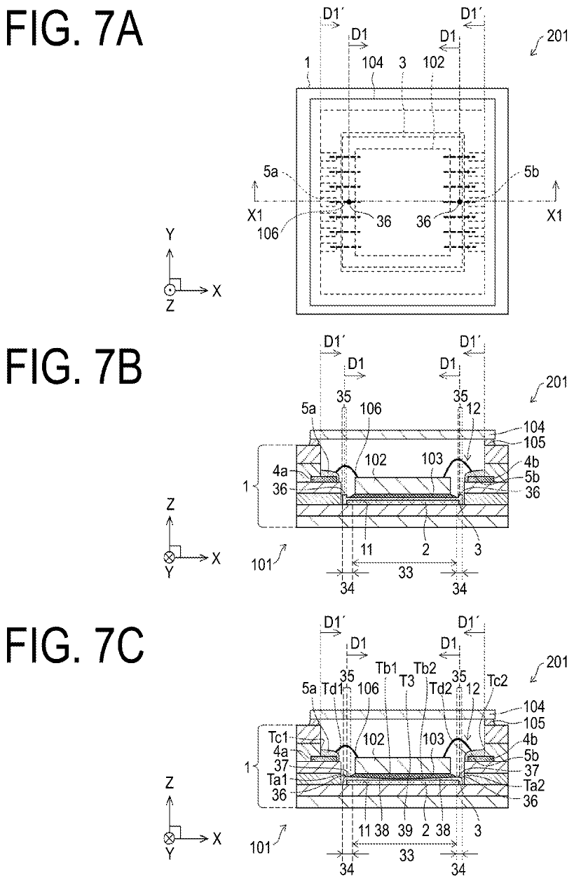

FIG. 7A is a top view illustrating the appearance of the electronic device 201 according to the third embodiment of the present disclosure, FIG. 7B is a vertical cross-sectional view corresponding to a line X1-X1 in FIG. 7A, and FIG. 7C is a variation of FIG. 7B.

In the electronic device 201 according to the third embodiment of the present disclosure, the first metal film 3 has the thick film portion 35 on both outer sides of the first region 33 with respect to the first region 33 in a cross-sectional view in the film thickness direction of the substrate 1. Thus, the effect of the thick film portion 35 can be obtained at both ends of the first metal film 3 in a cross-sectional view.

In the electronic device 201 according to the third embodiment of the present disclosure, the direction D1 is defined for each of the thick film portions 35 on both outer sides of the first region 33, and the thickness of the thick film portion 35 monotonically decreases in the direction D1. The two types of directions D1 defined for each of the thick film portions 35 on both outer sides of the first region 33 are opposite to each other. The components (1) and (2) are specific examples of the components that cause the monotonic decrease for each of the thick film portions 35 on both outer sides of the first region 33.

As a result, the components (1) and (2) in the example illustrated in FIGS. 3 and 4 can be effectively utilized to realize the thick film portion 35.

Of course, the thick film portion 35 may be provided on both outer sides of the first region 33 regardless of the monotonic decrease described in the present embodiment.

As illustrated in FIG. 7C, similarly to FIG. 6C, the thick film portion 35 may have the inclination 37 which is a portion where the film thickness continuously increases. As illustrated in FIG. 7C, similarly to FIG. 6C, in a cross-sectional view in the film thickness direction of the substrate 1, the first region 33 may have the inclined portion 38 in which the film thickness of the first region 33 decreases with increasing distance from the thick film portion 35.

In the example illustrated in FIG. 7C, the first region 33 has a thinnest portion 39 where the film thickness of the first metal film 3 is smallest. Accordingly, since the connection material 103 on the thinnest portion 39 is unlikely to flow outward, unintentional outward flow of the connection material 103 can be further reduced. The thinnest portion 39 may be located at the center portion of the substrate 1 in a plan view. As a result, the connection material 103 can be suppressed from flowing out of the mounting region.

As illustrated in FIG. 7C, the points Ta1 and Tb1 of the first metal film 3 are defined from the upstream side of one of the two kinds of directions D1, and the points Ta2 and Tb2 of the first metal film 3 are defined from the upstream side of the other of the two kinds of directions. The thickness of the thinnest portion 39 is denoted by T3. At this time, the thickness of the first metal film 3 satisfies the relations of the thinnest portion 39 (thickness T3)<point Tb1<point Ta1, and the thinnest portion 39 (thickness T3)<point Tb2<point Ta2.

Fourth Embodiment

Hereinafter, the electronic device 201 according to a fourth embodiment of the present disclosure will be described.

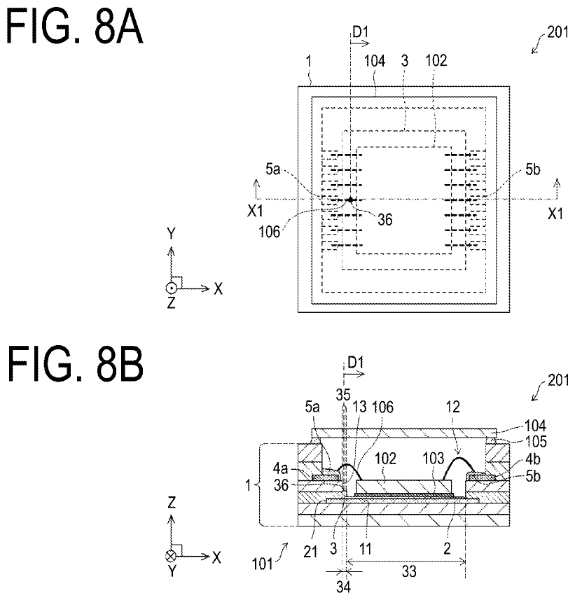

FIG. 8A is a top view illustrating the appearance of the electronic device 201 according to the fourth embodiment of the present disclosure, and FIG. 8B is a vertical cross-sectional view corresponding to the line X1-X1 in FIG. 8A.

In the electronic device 201 according to the fourth embodiment of the present disclosure, the end portion 21 of the metallized layer 2 is not covered with the first metal film 3. In this manner, a part of the metallized layer 2 may be covered with the first metal film 3. Thus, the amount of nickel and gold used to form the first metal film 3 can be reduced.

The end portion 21 of the metallized layer 2 which is not covered with the first metal film 3 may be exposed on the surface of the substrate 1. On the other hand, as illustrated in FIG. 8B, when the substrate 1 has a configuration in which the opening 12 is formed, the metallized layer 2 may be embedded in the substrate 1 from an inner wall 13 defining the opening 12.

### Second Metal Film

Hereinafter, the electrode pads 4a and 4b, the second metal films 5a and 5b, and the bonding wire 106 will be described with reference to the above-described embodiments. As the configuration of each of the electronic element 102, the connection material 103, the lid body 104, the lid bonding material 105, the substrate 1, the metallized layer 2, and the first metal film 3, the configuration illustrated in each of the embodiments described above can be appropriately used.

The electrode pads 4a and 4b are located on the surface of substrate 1, and more specifically, are provided on the side of the substrate 1 on which the electronic element 102 is to be mounted (upper surface of substrate 1). The electrode pads 4a and 4b are electrically connected to the electronic element 102. In each of the above-described embodiments, the number of electrode pads is two, but is not limited thereto, and the number of electrode pads may be one, or may be three or more.

An electrode may be provided on the surface of the substrate 1. The electrode may electrically connect the electronic element mounting substrate 101 to an external circuit board, or may electrically connect the electronic device 201 to an external circuit board.

Inside the substrate 1, internal wiring formed between a plurality of layers and a through-hole conductor vertically connecting the internal wiring may be provided. The internal wiring and the through-hole conductor may be exposed on the surface of the substrate 1. The electrode may be electrically connected to the electrode pads 4a and/or 4b by the internal wiring and the through-hole conductor.

When the substrate 1 is made of an electrically insulating ceramic, the electrode pads 4a and 4b are made of, for example, any one of tungsten, molybdenum, manganese, silver, and copper, or an alloy containing at least one of them. When the substrate 1 is made of a resin, the electrode pads 4a and 4b are made of, for example, any one of copper, gold, aluminum, nickel, molybdenum, and titanium, or an alloy containing at least one of these. The same applies to each of the electrode, the internal wiring, and the through-hole conductor.

The second metal films 5a and 5b are located on the surface of the substrate 1. To be more specific, the second metal films 5a and 5b are provided on the surfaces of the electrode pads located on the surface of the substrate 1. The second metal film is provided on the surface of each electrode pad.

As illustrated in FIG. 2B, the second metal film 5, which is any one of the second metal films 5a and 5b, includes a nickel coating 51 and a gold coating 52. The nickel coating 51 contains nickel as a main component, and is provided on the substrate 1 side with respect to the gold coating 52. The film thickness of the nickel coating 51 is, for example, from 0.03 μm to 3.0 μm. The gold coating 52 contains gold as a main component, and is provided on the opposite side to the substrate 1 with respect to the nickel coating 51, covering at least a part of the nickel coating 51. That is, the gold coating 52 may cover the entirety of the nickel coating 51, or may cover a part of the nickel coating 51. The film thickness of the gold coating 52 is, for example, from 0.03 μm to 0.30 μm. As described above, the second metal film 5 preferably has a layered structure, but may have a single-layer structure.

The bonding wire 106 is wiring for electrically connecting the electronic element 102 and the second metal film 5 (and thus the electrode pad 4). Although not illustrated, the electrode pad 4 is one of the electrode pads 4a and 4b corresponding to the second metal film 5 for the sake of convenience.

In the above description with reference to FIGS. 3 to 5, the nickel coating 31 and the gold coating 32 may be regarded as the nickel coating 51 and the gold coating 52, respectively. Thus, the description with reference to FIGS. 3 to 5 can be interpreted as an example of a method of providing the gold coating 52 on the surface of the nickel coating 51 (covering at least a part of the nickel coating 51).

The second metal films 5a and 5b located on the surface of the substrate 1 have surfaces 53a and 53b inclined with respect to the surface of the substrate 1, respectively. The surface of the substrate 1 refers to, for example, an upper surface of the substrate 1 or a surface on which an element is to be mounted. Here, it can be said that the surfaces 53a and 53b being inclined with respect to the surface of the substrate 1 more specifically means that the surfaces 53a and 53b are inclined with respect to the internal wall surfaces 14a and 14b of the substrate 1, respectively. In the second metal films 5a and 5b, the thicknesses of the second metal films 5a and 5b monotonically decrease in a direction D1′ that is the same as the direction D1 from the peak thickness portion 36 of the thick film portion 35 having a maximum thickness in the thick film portion 35 toward the inside of the first metal film 3 in a plan view of the substrate 1.

As illustrated in FIG. 1B, points Tc to Tf of the second metal film 5a and 5b are defined from the upstream side in the direction D1′. At this time, the thicknesses of the first metal film 3 and the second metal films 5a and 5b satisfy the relation of point Tf<point Te<point Tb<point Ta<point Td<point Tc.

As illustrated in FIG. 7C, the points Tc1 and Td1 of the second metal film 5a are defined from the upstream side of one of the two kinds of directions D1′, and the points Tc2 and Td2 of the second metal film 5b are defined from the upstream side of the other of the two kinds of directions. At this time, the thicknesses of the first metal film 3 and the second metal films 5a and 5b satisfy the relations of the thinnest portion 39 (thickness T3)<point Tb1<point Ta1<point Td1<point Tc1, and the thinnest portion 39 (thickness T3)<point Tb2<point Ta2<point Td2 <point Tc2.

When the inclination directions of the second metal films 5a and 5b in the same row are constant, the angle formed with the capillaries is easily kept constant, and wire bonding can be stably performed. Variations in the position of the wire bond contact can be reduced. Therefore, wire bonding defects can be reduced.

### Conclusion

An electronic element mounting substrate according to a first aspect of the present disclosure includes: a substrate having, on an upper surface thereof, a mounting region on which an electronic element is to be mounted; and a first metal film located in the mounting region, in which the first metal film has a first region including a center portion of the first metal film and a second region located in at least a part of a periphery of the first region, and the second region has a thick film portion in which a film thickness of the second region is greater than a film thickness of the first region.

When the electronic element is mounted, generally, the electronic element is brought close to the mounting region while the mounting region and the rear surface of the electronic element are kept substantially parallel to each other. Accordingly, the vicinity of the thick film portion comes close to and comes into contact with the rear surface of the electronic element earlier than the first region. Accordingly, the movement of the connection material substantially from the thick film portion to the first region can be controlled. Therefore, on the side of the thick film portion, the connection material that connects the mounting region and the electronic element can be suppressed from unintentionally flowing to the outside.

Since the step and/or the inclination is formed on the upper surface of the first metal film, the connection material flows from a high place to a low place on the upper surface of the first metal film, and spreading of the connection material can be promoted.

According to a second aspect of the present disclosure, in the electronic element mounting substrate according to the first aspect, in the thick film portion, a thickness of the thick film portion monotonically decreases in a direction from a peak thickness portion having a maximum thickness toward an inner side of the first metal film in a plan view of the substrate.

According to the configuration, the thick film portion can be realized by effectively using a rough trend of the distribution of the film thickness of the first metal film.

According to a third aspect of the present disclosure, in the electronic element mounting substrate according to the first or second aspect, the first metal film has the thick film portion on both outer sides of the first region with respect to the first region in a cross-sectional view in a film thickness direction of the substrate.

According to the configuration, the effect of the thick film portion can be obtained at both ends of the first metal film in a cross-sectional view.

According to a fourth aspect of the present disclosure, in the electronic element mounting substrate according to any one of the first to third aspects, the thick film portion has a portion in which the film thickness continuously increases.

According to the configuration, since the corners of the thick film portion are rounded, physical damage to the electronic element due to the electronic element hitting the corners of the thick film portion can be reduced.

According to a fifth aspect of the present disclosure, in the electronic element mounting substrate according to any one of the first to fourth aspects, in a cross-sectional view in a film thickness direction of the substrate, the first region has an inclined portion in which a film thickness of the first region decreases with increasing distance from the thick film portion.

According to the configuration, the movement of the connection material from the thick film portion to the first region side can be controlled more strongly.

According to a sixth aspect of the present disclosure, in the electronic element mounting substrate according to any one of the first to fifth aspects, the first region has a portion in which the first metal film has a smallest thickness.

According to the configuration, since the connection material on the portion where the film thickness of the first metal film is the smallest does not easily flow to the outside, unintentional outward flow of the connection material can be further reduced.

According to a seventh aspect of the present disclosure, the electronic element mounting substrate according to any one of the first to sixth aspects further includes a metallized layer, and at least a portion of the metallized layer is covered with the first metal film.

According to an eighth aspect of the present disclosure, in the electronic element mounting substrate according to any one of the first to seventh aspects, a maximum value of a film thickness of the thick film portion is from 0.06 μm to 3.30 μm.

According to a ninth aspect of the present disclosure, in the electronic element mounting substrate according to any one of the first to eighth aspects, the first metal film includes: a nickel coating containing nickel as a main component; and a gold coating provided covering at least a part of the nickel coating, the gold coating containing gold as a main component, in which a maximum value of a film thickness of the gold coating in the thick film portion is from 0.03 μm to 0.30 μm.

According to a tenth aspect of the present disclosure, the electronic element mounting substrate according to any one of the first to ninth aspects further includes a second metal film located on a surface of the substrate, in which the second metal film has a surface inclined with respect to the surface of the substrate.

According to an eleventh aspect of the present disclosure, in the electronic element mounting substrate according to the tenth aspect, in the second metal film, a thickness of the second metal film monotonically decreases in a direction identical to a direction from a peak thickness portion of the thick film portion having a maximum thickness in the thick film portion toward an inner side of the first metal film in a plan view of the substrate.

The present disclosure is not limited to each of the embodiments described above, and various modifications can be made within the scope indicated by the claims, and an embodiment obtained by appropriately combining technical means disclosed in different embodiments is also included in a technical scope of the present disclosure.

### REFERENCE SIGNS

1 Substrate
2 Metallized layer
3 First metal film
4a, 4b Electrode pad
5, 5a, 5b Second metal film
11 Mounting region
12 Opening
13 Inner wall
21 End portion of metallized layer
31, 51 Nickel coating
32, 52 Gold coating
33 First region
34 Second region
35 Thick film portion
36 Peak thickness portion
37 Inclination
38 Inclined portion
39 Thinnest portion
53a 53b Surface of second metal film
101 Electronic element mounting substrate
102 Electronic element
103 Connection material
104 Lid body
105 Lid bonding material
106 Bonding wire
201 Electronic device
301 Intermediate body
302 Jig
303, 304 Surface
305, 306 Gold electrode
307 Gold complex bath
308 Trend
309 Normal direction
D1 Direction from peak thickness portion toward inner side of first metal film in plan view of substrate
D′ Direction identical to direction D1
T1 to T3 Thickness

1. An electronic element mounting substrate comprising:
a substrate comprising a mounting region on which an electronic element is to be mounted on an upper surface; and
a first metal film located in the mounting region, wherein
the first metal film comprises a first region comprising a center portion of the first metal film and a second region located in at least a part of a periphery of the first region, and
the second region comprises a thick film portion in which a film thickness of the second region is greater than a film thickness of the first region.

2. The electronic element mounting substrate according to claim 1, wherein
in the thick film portion, a thickness of the thick film portion monotonically decreases in a direction from a peak thickness portion having a maximum thickness toward an inner side of the first metal film in a plan view of the substrate.

3. The electronic element mounting substrate according to claim 1, wherein
the first metal film comprises the thick film portion on both outer sides of the first region with respect to the first region in a cross-sectional view in a film thickness direction of the substrate.

4. The electronic element mounting substrate according to claim 1, wherein
the thick film portion comprises a portion where a film thickness continuously increases.

5. The electronic element mounting substrate according to claim 1, wherein,
in a cross-sectional view in a film thickness direction of the substrate, the first region comprises an inclined portion in which a film thickness of the first region decreases as a distance from the thick film portion increases.

6. The electronic element mounting substrate according to claim 1, wherein
the first region comprises a portion where a film thickness of the first metal film is smallest.

7. The electronic element mounting substrate according to claim 1, further comprising a metallized layer, wherein
at least a part of the metallized layer is covered with the first metal film.

8. The electronic element mounting substrate according to claim 1, wherein
a maximum value of a film thickness of the thick film portion is from 0.06 μm to 3.30 μm.

9. The electronic element mounting substrate according to claim 1, wherein
the first metal film comprises:
a nickel coating containing nickel as a main component; and
a gold coating provided covering at least a part of the nickel coating, the gold coating containing gold as a main component, wherein
a maximum value of a film thickness of the gold coating in the thick film portion is from 0.03 μm to 0.30 μm.

10. The electronic element mounting substrate according to claim 1, further comprising:
a second metal film located on a surface of the substrate, wherein
the second metal film comprises a surface inclined with respect to the surface of the substrate.

11. The electronic element mounting substrate according to claim 10, wherein
in the second metal film, a thickness of the second metal film monotonically decreases in a direction identical to a direction from a peak thickness portion of the thick film portion having a maximum thickness in the thick film portion toward an inner side of the first metal film in a plan view of the substrate.
